(19) United States
(12) Patent Application Publication
(10) Pub. No.: US 2026/0371739 A1
(43) Pub. Date: Nov. 19, 2026

(54) PREPARATION METHOD FOR STACKED TRANSISTOR, AND STACKED TRANSISTOR, DEVICE AND APPARATUS

(71) Applicants: BEIJING INTELLECTUAL PROPERTY OPERATIONS MANAGEMENT CO., LTD, Beijing (CN); PEKING UNIVERSITY, Beijing (CN)

(72) Inventors: Heng WU, Beijing (CN); Yandong GE, Beijing (CN); Haoran LU, Beijing (CN); Runsheng WANG, Beijing (CN); Ming LI, Beijing (CN); Ru HUANG, Beijing (CN)

(21) Appl. No.: 19/471,107

(22) PCT Filed: Aug. 19, 2024
(86) PCT No.: PCT/CN2024/113079

§ 371 Date: Sep. 30, 2025

(30) Foreign Application Priority Data
Jan. 15, 2024 (CN) 202410057642.9
Jan. 30, 2024 (CN) 202410130550.9

(51) Int. Cl. H10D 88/00; H10D 62/10; H10D 84/01; H10D 84/83

(52) U.S. Cl. CPC H10D 88/01; H10D 84/0151; H10D 84/0158; H10D 84/832; H10D 84/834; H10D 88/00; H10D 62/121

(57) ABSTRACT

Provided in the present disclosure are a preparation method for a stacked transistor, and a stacked transistor, a device and an apparatus. The method comprises: forming on a substrate a first active structure, a first intermediate layer and a second active structure, which are sequentially stacked; forming a first transistor on the basis of the first active structure; flipping a wafer and removing the substrate, so as to expose the second active structure; forming a second transistor on the basis of the second active structure, wherein the first transistor and the second transistor are self-aligned in a direction perpendicular to a channel; and forming an isolation dielectric structure on the basis of the first intermediate layer, wherein the material of the isolation dielectric structure is different from the material of the first intermediate layer, and the isolation structure is used for isolating the first active structure from the second active structure.

### CROSS-REFERENCES TO RELATED APPLICATIONS

The present application is filed based on and claims priority to the Chinese Patent Application No. 202410057642.9 filed on Jan. 15, 2024 and entitled “METHOD FOR PREPARING STACKED TRANSISTOR, STACKED TRANSISTOR, DEVICE AND APPARATUS”, and the Chinese Patent Application No. 202410130550.9 filed on Jan. 30, 2024 and entitled “METHOD FOR PREPARING STACKED TRANSISTOR, STACKED TRANSISTOR, DEVICE AND APPARATUS”, the entire contents of which are hereby incorporated herein by reference.

### TECHNICAL FIELD

The present disclosure relates to the technical field of semiconductors, and more particularly relates to a method for fabricating a stacked transistor, a stacked transistor, a device, and an apparatus.

### BACKGROUND

With the deepening of Moore's Law, a hot issue of research and development in the current industry is to continue promoting the miniaturization of transistor size. Two or more layers of transistors are integrated in vertical space in the stacked transistor to further increase transistor integration density, which become one of the important technologies for the miniaturization of the size of integrated circuits.

When a conventional monolithic stacking scheme is used to fabricate a stacked transistor, it is a technical difficulty to implement electrical isolation of an active region.

### SUMMARY

The present disclosure provides a method for fabricating a stacked transistor, a stacked transistor, a device, and an apparatus.

A first aspect of the present disclosure provides a method of fabricating a stacked transistor. The method includes: forming a first active structure, a first intermediate layer, and a second active structure disposed and stacked in sequence on a substrate; forming a first transistor based on the first active structure; flipping, and removing the substrate to expose the second active structure; forming a second transistor based on the second active structure, where the first transistor and the second transistor are self-aligned in a direction perpendicular to a channel; forming an isolation dielectric structure based on the first intermediate layer, where the material of the isolation dielectric structure is different from the material of the first intermediate layer, and the isolation structure is used to isolate the first active structure from the second active structure.

A second aspect of the present disclosure provides a stacked transistor. The stacked transistor includes: a first transistor; a second transistor, where the first transistor and the second transistor is self-aligned in a direction perpendicular to a channel; an isolation dielectric structure located between a first active structure of the first transistor and a second active structure of the second transistor, where the isolation dielectric structure is used for isolating the first active structure from the second active structure.

A third aspect of the present disclosure provides a semiconductor device. The semiconductor device includes the stacked transistor as provided in the second aspect.

A fourth aspect of the present disclosure provides an electronic device. The electronic device includes a circuit board and the semiconductor device as provided in the third aspect, where the semiconductor device is disposed on the circuit board.

In the present disclosure, electrical isolation between the first active structure and the second active structure can be achieved by providing an isolation dielectric structure between the first active structure and the second active structure.

It is to be understood that the above general description and the following detailed description are merely exemplary and explanatory, and do not limit the present disclosure.

### BRIEF DESCRIPTION OF THE DRAWINGS

The accompanying drawings herein, which are incorporated into and constitute a part of the specification, illustrate embodiments consistent with the present disclosure and, together with the specification, serve to explain the principles of the embodiments of the present disclosure.

FIG. 1 is a schematic flow diagram of a first implementation of a method for fabricating a stacked transistor according to an embodiment of the present disclosure.

FIG. 2 is a first schematic structural diagram of a stacked transistor according to an embodiment of the present disclosure.

FIGS. 3A-3F are schematic diagrams of a first fabrication process of a stacked transistor according to an embodiment of the present disclosure.

FIG. 4 is a second schematic structural diagram of a stacked transistor according to an embodiment of the present disclosure.

FIGS. 5A to 5C are schematic diagrams of a second fabrication process of a stacked transistor according to an embodiment of the present disclosure.

FIG. 6 is a third schematic structural diagram of a stacked transistor according to an embodiment of the present disclosure.

FIGS. 7A-7F are schematic diagrams of a third fabrication process of a stacked transistor according to an embodiment of the present disclosure.

FIGS. 8A to 8D are schematic diagrams of a fourth fabrication process of a stacked transistor according to an embodiment of the present disclosure.

### DESCRIPTION OF REFERENCE NUMBERS

Stacked transistor 10; first transistor 11; first active structure 111; first gate structure 112; first source-drain structure 113; first source-drain metal 114; first interlayer dielectric layer 115; first gate dielectric layer 116; first spacer 117; first metal interconnection layer 118; second transistor 12; second active structure 121; second gate structure 122; second source-drain structure 123; second source-drain metal 124; second interlayer dielectric layer 125; second gate dielectric layer 126; second spacer 127; second metal interconnection layer 128; isolation medium structure 13; shallow trench isolation layer 14; first insulation layer 15; carrier wafer 16; substrate 21; bottom substrate 211; intermediate sacrificial layer 212; top substrate 213; fin structure 22; first fin structure 221; second fin structure 222; first intermediate layer 223; shallow trench isolation structure 23; second shallow trench isolation structure 231; first shallow trench isolation structure 232; third shallow trench isolation structure 233; fourth shallow trench isolation structure 234; first dummy gate structure 241; second dummy gate structure 242; pillar structure 25; first portion 251 of the pillar structure; second portion 252 of the pillar structure; first inner side wall 26; first trench 27; first filling structure 28; first semiconductor material layer 31; second semiconductor material layer 32; third semiconductor material layer 33.

### DETAILED DESCRIPTION

Herein, exemplary embodiments will be described in detail, examples of which are shown in the accompanying drawings. The following description concerns the drawings, the same reference number in different drawings denotes the same or similar elements unless otherwise indicated. The implementations described in the following exemplary embodiments do not represent all implementations consistent with the embodiments of the present disclosure. Rather, the implementations are merely examples of devices and methods with which some aspects of embodiments of the present disclosure are consistent.

The terminology used in embodiments of the present disclosure is merely for the purpose of describing particular embodiments, and is not intended to limit the embodiments of the present disclosure. As used in the present disclosure, the singular forms “a” and “the” are also intended to include the plural forms unless the context clearly indicates otherwise. It should also be understood that the term “and/or” as used herein refers to and includes any or all possible combinations of one or more associated listed items.

With the continuous deepening of Moore's Law, a hot issue of research and development in the current industry after the technology node of gate-all-around FET (GAA) is to continue promoting the miniaturization of transistor size. The stacked transistor can realize the integration of two or more layers of transistors in vertical space through three-dimensional transistor stacking, which is beneficial to further increase transistor integration density and improve circuit performance. It is considered to be one of the important technologies to continue the miniaturization of the size of integrated circuits.

In an embodiment, there are two schemes for a fabrication process of the stacked transistor, the first one is a monolithic stacking scheme, and the second one is a sequential scheme.

In the first scheme, N-channel field effect transistors (NFETs) and P-channel field effect transistors (PFETs) are fabricated on the same substrate, and wafer bonding technology is not used. This decides that transistors at the same layer must be of the same type, i.e. NFET or PFET. Moreover, the upper and lower transistors should be strictly in the same plane space, and there is no alignment deviation. The advantage of this scheme is good integration density. The shortcomings of this scheme include (1) complex process, which requires a lot of development and optimization of process technology; (2) poor design flexibility, each layer of transistors has a fixed polarity, and two layers of transistors are required to form a basic complementary metal-oxide-semiconductor (CMOS) circuit.

The second scheme is based on wafer bonding and layer-by-layer processing. The upper transistor is prepared by bonding a wafer on top of the fabricated lower transistor, and the two transistors are stacked vertically. However, in the scheme, the temperature should be strictly controlled during the thermal process of processing the upper transistor, to avoid affecting the lower transistor and interconnection lines. The advantage of this scheme is that with the benefit of wafer bonding, the device structures, channel crystal orientations and even channel materials used in the upper and lower transistors can be optimized to obtain good and matched device performance. At present, there are the following technical challenges in this scheme: (1) preparation of high-quality active layer of the upper transistor; (2) thinning and defect control of upper-layer bonded wafers; (3) alignment errors in the upper and lower transistors, which require extremely high lithography accuracy.

When a monolithic stacked transistor is used, the active regions of the upper transistor and the lower transistor should be electrically isolated. The current methods include: (1) forming a natural electrical isolation layer by using a silicon-on-insulator (SOI) substrate and a buried oxide (BOX) layer; (2) forming an electrical isolation layer by ion implantation of P-type ions, N-type ions or oxygen ions.

However, the SOI substrate is expensive, and it is difficult to obtain the SOI substrate with suitable thicknesses to the BOX layer and the device layer. The process control of ion implantation is difficult, and the diffusion effect of implanted ions will have a great impact on the thermal budget of subsequent processes, and the implanted ions will also damage the device structure.

In order to solve the above-described technical problems, the embodiments of the present disclosure provide a method for fabricating a stacked transistor to achieve electrical isolation between a first active structure and a second active structure.

In some embodiments, the above stacked transistor may be applied to semiconductor devices such as memories, processors, and the like.

In an embodiment, the stacked transistor may comprise at least two transistors, such as a first transistor and a second transistor. The first transistor and the second transistor are disposed to be opposite to each other. A first active structure in the first transistor and a second active structure in the second transistor are formed in the same process, and the first active structure and the second active structure are self-aligned.

In some embodiments, the first transistor and the second transistor in the stacked transistor may be of the same type of transistor, such as any of a fin-shaped field effect transistor, a nanosheet field effect transistor, a planar transistor, and a vertical field effect transistor.

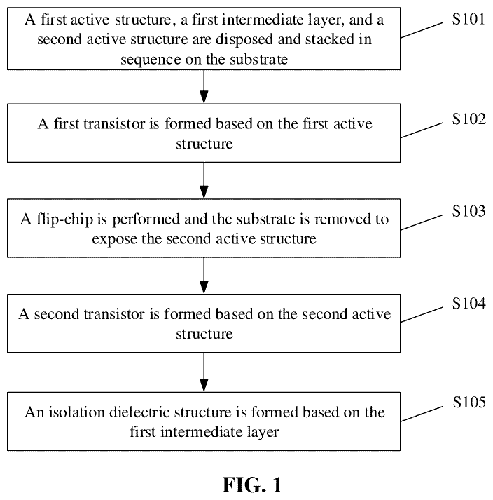

FIG. 1 is a schematic flow diagram of a first implementation of a method for fabricating a stacked transistor according to an embodiment of the present disclosure, and as shown in FIG. 1, the method for fabricating a stacked transistor may include steps S101 to S105.

At step S101, a first active structure, a first intermediate layer and a second active structure are disposed and stacked in sequence on the substrate.

It is understood that a substrate is provided, and the first active structure, the first intermediate layer and the second active structure are obtained by etching on the substrate by the same process, and the first intermediate layer is located between the first active structure and the second active structure.

In some embodiments, the first active structure, the first intermediate layer and the second active structure may be made of the same material, such as silicon (Si).

In some embodiments, when the first active structure, the first intermediate layer and the second active structure are made of the same material, and the stacked transistor is a fin-shaped field effect transistor, the above step S101 may include: etching the substrate to form multiple fin structures, the fin structure is divided into three parts from top to bottom, the first part is the first active structure, the second part is the first intermediate layer, and the third part is the second active structure.

In some embodiments, in case where the first active structure, the first intermediate layer and the second active structure are made of the same material, and the stacked transistor is gate-all-around transistor, the step S101 may include etching the substrate to form a pillar structure.

In some embodiments, the substrate is formed by alternately disposing the silicon layer and the silicon germanium layer. The pillar structure is divided into three parts from top to bottom, the first part is a first active structure, the second part is a first intermediate layer, and the third part is a second active structure.

In some embodiments, when the first active structure, the first intermediate layer, and the second active structure are made of the same material, and the stacked transistor is a planar transistor, the above step S101 may include: etching the substrate to form a blocky structure. The blocky structure is divided into three parts from top to bottom, the first part is the first active structure, the second part is the first intermediate layer, and the third part is the second active structure.

In some embodiments, since the stacked transistor includes two transistors (i.e., a first transistor and a second transistor), and the first active structure of the first transistor and the second active structure of the second transistor are formed by the same etching process, a large etching depth can be adopted when etching the substrate. The height of the etched fin-shaped structure (which may also be a pillar structure or a blocky structure) may be greater than 100 nanometers (nm). It should be noted that the height of the fin-shaped structure may be set according to the actual situation, which is not limited in the embodiment of the present disclosure.

In some embodiments, the substrate may include a top substrate, an intermediate sacrificial layer, and a bottom substrate disposed and stacked in sequence. The top substrate and the bottom substrate are made of the same material, such as a silicon material, and the intermediate sacrificial layer is made of a different material from the bottom substrate and the top substrate. The first active structure is formed by etching the top substrate, the second active structure is formed by etching the bottom substrate, and the first intermediate layer is formed by etching the intermediate sacrificial layer.

In some embodiments, in case where the substrate includes the top substrate, the intermediate sacrificial layer and the bottom substrate disposed and stacked in sequence, the fabrication process of the substrate may include: epitaxially applying the material of a sacrificial layer on an original substrate (i.e., the bottom substrate) to form an intermediate sacrificial layer; epitaxially applying the same semiconductor material as the bottom substrate over the intermediate sacrificial layer to form the top substrate. The substrate formed by the above-described fabrication method includes the top substrate, the intermediate sacrificial layer and the bottom substrate that are disposed and stacked in sequence. The top substrate is used to fabricate a front-side transistor (i.e., the first transistor) and the bottom substrate is used to fabricate a back-side transistor (i.e., the second transistor).

In some embodiments, in case where the substrate includes a top substrate, an intermediate sacrificial layer, and a bottom substrate disposed and stacked in sequence, the material of the intermediate sacrificial layer may be a silicon germanium (SiGe) material or other semiconductor materials, which is not limited in the embodiments of the present disclosure.

In some embodiments, in case where the substrate includes the top substrate, the intermediate sacrificial layer and the bottom substrate that are sequentially disposed and stacked, the arrangement of the substrates is different when the type of the stacked transistor is different. When the stacked transistor is any of a fin-shaped field effect transistor, a planar transistor, and a vertical field effect transistor, the bottom substrate and the top substrate may be made of a silicon material. When the stacked transistor is a nanosheet field effect transistor, the bottom substrate and the top substrate may be a stacked layer formed by alternating depositing silicon and silicon germanium.

In some embodiments, in case where the substrate includes the top substrate, the intermediate sacrificial layer and the bottom substrate that are sequentially disposed and stacked, the height of the top substrate can be designed according to actual needs, such as 50 nm, the height of the bottom substrate is larger than that of the top substrate, and the height of the intermediate sacrificial layer is smaller than the height of the top substrate.

In some embodiments, in case where the substrate includes the top substrate, the intermediate sacrificial layer, and the bottom substrate that are sequentially disposed and stacked, the above-described step S101 may include: patterning an active structure through standard process steps, and sequentially etching the top substrate, the intermediate sacrificial layer, and the bottom substrate to obtain the active structure. The active structure includes a first active structure in a first transistor and a second active structure in a second transistor. A larger etching depth can be adopted when etching the substrate. The height of the active structure should be greater than a preset height threshold, and the height of the active structure may be greater than 100 nm. It should be noted that the height of the active structure may be designed according to actual needs, which is not limited in the embodiments of the present disclosure.

In some embodiments, in case where the substrate includes the top substrate, the intermediate sacrificial layer, and the bottom substrate that are sequentially disposed and stacked, when the stacked transistor is a fin-shaped field effect transistor, the above-described step S101 may include: sequentially etching the top silicon substrate, the intermediate silicon germanium sacrificial layer and the bottom silicon substrate to form a plurality of fin structures. The upper half (i.e., the etched top silicon substrate) of the fin structure is the first active structure, and the lower half (i.e., the etched bottom silicon substrate) of the fin structure is the second active structure.

In some embodiments, in case where the substrate includes the top substrate, the intermediate sacrificial layer and the bottom substrate that are sequentially disposed and stacked, when the stacked transistor is a nanosheet field effect transistor, the above step S101 may include: sequentially etching the top stacked substrate, the intermediate silicon germanium sacrificial layer and the bottom stacked substrate to form a pillar structure. The upper half (i.e., the etched top stacked substrate) of the pillar structure is the first active structure, and the lower half (i.e., the etched bottom stacked substrate) of the pillar structure is the second active structure.

In some embodiments, in case where the substrate includes the top substrate, the intermediate sacrificial layer and the bottom substrate that are sequentially disposed and stacked, when the stacked transistor is a planar transistor, the above step S101 may include: sequentially etching the top silicon substrate, the intermediate silicon germanium sacrificial layer and the bottom silicon substrate to form a blocky structure. The upper half (i.e. the etched top silicon substrate) of the blocky structure is the first active structure, and the lower half (i.e. the etched bottom silicon substrate) of the blocky structure is the second active structure.

In some embodiments, in case where the substrate includes the top substrate, the intermediate sacrificial layer and the bottom substrate that are sequentially disposed and stacked, when the stacked transistor is a vertical field effect transistor, the above step S101 may include: sequentially etching the top silicon substrate, the intermediate silicon germanium sacrificial layer and the bottom silicon substrate to form a pillar structure. The upper half (i.e., the etched top silicon substrate) of the pillar structure is the first active structure, and the lower half (i.e., the etched bottom silicon substrate) of the pillar structure is the second active structure.

In some embodiments, when the stacked transistor is a fin-shaped field effect transistor, after the plurality of fin structures are formed, the plurality of fin structures may be subjected to a fin-cut process such that the heights of the plurality of fin structures are consistent.

In some possible embodiments, in case where the substrate includes the top substrate, the intermediate sacrificial layer and the bottom substrate that are sequentially disposed and stacked, after step S101, the above method may further include filling the oxide over the active structure to form a second shallow trench isolation structure (STI). The height of the second shallow trench isolation structure is greater than the height of the active structure.

In some embodiments, the oxide for forming the second shallow trench isolation structure may be any of the following: silicon nitride (SiN, Si3N4), silicon dioxide (SiO2), silicon oxycarbide (SiCO), or the like.

In some embodiments, after forming the second shallow trench isolation structure, the above method may further include: performing a chemical-mechanical planarization (CMP) process on the second shallow trench isolation structure.

In some embodiments, the chemical-mechanical planarization (CMP) process is performed on the second shallow trench isolation structure, so that the second shallow trench isolation structure in different regions have the same corrosion depth when the second shallow trench isolation structure is etched, and the exposed active structure have the same height.

In some possible embodiments, in case where the substrate includes the top substrate, the intermediate sacrificial layer and the bottom substrate that are sequentially disposed and stacked, after the above step S101, the method may further include: forming first dummy gate structures disposed at intervals on the surface of the first active structure and a first shallow trench isolation structure surrounding the second active structure.

It can be understood that the first shallow trench isolation structure is formed before the second shallow trench isolation structure. After the second shallow trench isolation structure is formed, the second shallow trench isolation structure surrounding the first active structure may be removed by etching, the second shallow trench isolation structure that is not etched is taken as the first shallow trench isolation structure, and the first active structure is exposed, and the first dummy gate structure may be formed based on the first active structure.

In step S102, a first transistor is formed based on the first active structure.

It is understood that after forming the first active structure, other structures such as a first source-drain structure, a first gate structure and a first metal interconnection layer, in the first transistor may be formed based on the first active structure.

In some possible embodiments, in case where the substrate includes the top substrate, the intermediate sacrificial layer and the bottom substrate that are sequentially disposed and stacked, the above-described step S102 may include: etching a part of the first active structure along an extending direction of the first active structure and forming a first source-drain structure; depositing a semiconductor material on the first active structure and the first source-drain structure to form a first interlayer dielectric layer; removing the first dummy gate structures and forming a first gate structure; removing a part of the first interlayer dielectric layer to form a first source-drain metal trench; depositing a metal material in the first source-drain metal trench to form a first source-drain metal; performing a back end of line process on the first interlayer dielectric layer and the first gate structure to form a first metal interconnection layer.

In some embodiments, the operation of etching a part of the first active structure along an extending direction of the first active structure and forming a first source-drain structure may include: etching to remove a part of the first active structure, which may provide a source-drain trench of the first transistor. With taking the first spacer as a mask, a strain material such as silicon germanium or silicon carbide is formed in the source-drain trench of the first transistor by selective epitaxial growth, to fill the source-drain trench of the first transistor, and a first source-drain structure is formed on the strain material by a heavy doping process.

It should be noted that, for convenience of explanation, the first source-drain structure mentioned in the embodiment of the present disclosure is an abbreviation, and refers to a first source structure and/or a first drain structure. In addition, the second source-drain structure, the first source-drain metal, the second source-drain metal, the source-drain trench and the like are all similar as the first source-drain structure, and “source-drain” is an abbreviation of “source and/or drain”.

In some embodiments, the operation of depositing a semiconductor material on the first active structure and the first source-drain structure to form a first interlayer dielectric layer may include: depositing an insulating material (such as silicon dioxide (SiO2)) over the first active structure and the first source-drain structure to form a first interlayer dielectric layer; The first interlayer dielectric layer may cover the first active structure and the first source-drain structure.

In some embodiments, the operation of removing the first dummy gate structures and forming the first gate structure may include etching to remove the first dummy gate structures, to expose a gate region of the first transistor, and depositing a metal material on the gate region of the first transistor to form the first gate structure of the first transistor.

In some embodiments, the metal materials of the first gate structure and the second gate structure may include tantalum nitride (TaN), titanium nitride (TiN), aluminum nitride (AlN), titanium aluminum carbide (TiAlC), or titanium aluminum nitride (TiAlN). The materials of the first gate structure and the second gate structure may be selected according to the actual situation, and are not limited to the metal materials listed above.

In some embodiments, the materials of the first gate structure and the second gate structure may be the same or different metal materials according to the actual situation, which is not limited in the embodiments of the present disclosure.

In some embodiments, before fabricating the first gate structure, the above method may further include: depositing a semiconductor material on a surface of the first active structure to form a first gate dielectric layer of the first transistor. The first gate dielectric layer is used to isolate the first active structure from the first gate structure.

In some embodiments, the operation of removing a part of the first interlayer dielectric layer to form a first source-drain metal trench and depositing a metal material in the first source-drain metal trench to form a first source-drain metal may include: etching a portion, above the first source-drain structure, of the first interlayer dielectric layer until an upper surface of the first source-drain structure is exposed, to form the first source-drain metal trench; and depositing a metal material in the first source-drain metal trench to obtain a first source-drain metal.

In some embodiments, the operation of performing a back end of line process over the first interlayer dielectric layer and the first gate structure to form a first metal interconnection layer may include: performing processing such as interconnected-line dielectric deposition, metal line formation, bonding pad formation and the like on the first interlayer dielectric layer and the first gate structure, to form the first metal interconnection layer of the first transistor.

In some possible embodiments, in case where the first active structure, the first intermediate layer and the second active structure are made of the same material, before the above step S102, the above method may further include: depositing a dielectric material on the first active structure, the first intermediate layer and the second active structure to form a shallow trench isolation structure, where the shallow trench isolation structure encloses the first active structure, the first intermediate layer and the second active structure; and removing the first portion of the shallow trench isolation structure to expose the first active structure.

In some embodiments, the dielectric material (which may also be an insulating material) for forming the shallow trench isolation structure may be any of the following: silicon nitride (SiN, Si3N4), SiO2, silicon oxycarbide (SiCO) or the like, or may be other insulating materials, which is not limited in the embodiments of the present disclosure.

In some embodiments, after forming the shallow trench isolation structure, the above method may further include: performing CMP process on the shallow trench isolation structure.

In some embodiments, with the CMP process on the shallow trench isolation structure, the shallow trench isolation structures in different regions have the same etching depth when the shallow trench isolation structure is etched, so that the top height of the exposed active structure is the same.

In some possible embodiments, in case where the first active structure, the first intermediate layer, and the second active structure are made of the same material, the above step S102 may include: sequentially forming a first dummy gate structure, a first spacer, a first source-drain structure and a first interlayer dielectric layer of the first transistor based on the first active structure; removing the first dummy gate structure and forming a first gate structure and a first gate dielectric layer; and performing a back end of line process on the first interlayer dielectric layer to form a first metal interconnection layer.

In some embodiments, the operation of sequentially forming a first dummy gate structure, a first spacer, a first source-drain structure and a first interlayer dielectric layer of the first transistor based on the first active structure may include: performing photolithography to open a gate region of the first transistor, and depositing a semiconductor material (such as polysilicon) on the gate region to form a first dummy gate structure of the first transistor; forming first spacer on both sides of the first dummy gate structure; etching to remove a part of the first active structure, which may provide a source-drain trench of the first transistor; with taking the first spacer as a mask, forming a strain material such as silicon germanium or silicon carbide in the source-drain trench of the first transistor by selective epitaxial growth, to fill the source-drain trench of the first transistor; forming a first source-drain structure on the strain material by a heavy doping process; depositing an insulating material (such as silicon dioxide) over the first active structure and the first source-drain structure to form a first interlayer dielectric layer, where the first interlayer dielectric layer may cover the first active structure and the first source-drain structure; removing the first dummy gate structure and depositing an insulating material on the surface of the first active structure, to form a first gate dielectric layer of the first transistor; depositing a metal material on the gate region to form a first gate structure; performing a back end of line process is performed on the first interlayer dielectric layer and the first gate structure to form a first metal interconnection layer.

In some embodiments, an active region is a collective term for a source region, a drain region and a channel region.

At step S103, a flip-chip process is performed and the substrate is removed, to expose the second active structure.

It will be appreciated that after the first transistor is formed, the first transistor is flipped such that the substrate is placed upward, and the substrate is removed to expose the second active structure.

In some possible embodiments, before the above step S103, the above method may further include: depositing an insulating material on the upper surface of the first transistor to form an insulating layer; and bonding the insulating layer and a carrier wafer.

In some embodiments, the bonded carrier wafer can provide physical support for the inverted first transistor, to effectively prevent the first transistor from being broken by external force during the fabrication of the second transistor.

In some possible embodiments, the above step S103 may include: flipping the first transistor; performing wafer thinning process and planarization process on the substrate, to a to expose the bottom of the second active structure.

It will be appreciated that after the first transistor is flipped, the bottom substrate is placed upward, the bottom substrate can be removed by the wafer thinning process and planarization process (such as CMP), and the CMP process is stopped until the first shallow trench isolation structure, so that the surface of the second active structure away from the first active structure is exposed accordingly.

In some embodiments, after the bottom substrate is removed, the first shallow trench isolation structure may be etched to be removed to expose the second active structure for subsequent fabrication of the second transistor,

In the process of etching the first shallow trench isolation structure, the first shallow trench isolation structure with a preset height may be retained as a shallow trench isolation layer, and the shallow trench isolation layer is located between the first gate structure and the second gate structure to isolate the first gate structure and the second gate structure.

In some possible embodiments, in case where the first active structure, the first intermediate layer and the second active structure are made of the same material, after the above step S103, the above method may further include: removing a portion of the second active structure away from the first active structure to form a first trench; depositing a second insulating material in the first trench to form a first filling structure; removing the second portion of the shallow trench isolation structure to expose the second active structure and the first intermediate layer.

It will be appreciated that after the substrate is removed, the shallow trench isolation structure is exposed, and in this case, the shallow trench isolation structure and the second active structure are horizontally aligned in a direction perpendicular to the substrate. Next, a portion of the second active structure may be etched by selective etching to form the first trench.

In some embodiments, the etching height (that is, the height of the first trench) may be set according to the actual situation, which is not limited in the embodiments of the present disclosure.

In some embodiments, a second insulating material is deposited in the first trench and above the shallow trench isolation structure, and the deposited second insulating material fills the first trench and covers the surface of the shallow trench isolation structure. Then, the deposited second insulating material is subjected to the CMP process, and the CMP is stopped until the surface of the shallow trench isolation structure, and the second insulating material in the first trench is not removed to form a first filling structure.

In some embodiments, the shallow trench isolation structure consists of a first portion enclosing the first active structure and a second portion enclosing the second active structure and the first intermediate layer.

In some possible embodiments, in case where the first active structure, the first intermediate layer and the second active structure are made of the same material and the first filling structure is formed, the operation of removing a portion, covering the first semiconductor material layer, of the second semiconductor material layer to expose the first semiconductor material layer may include: removing a portion of the second semiconductor material layer covering the first semiconductor material layer and a portion of the second semiconductor material layer covering the first filling structure, to expose the first semiconductor material layer and the first filling structure. After an oxidation treatment is performed on the first intermediate layer to form an isolation dielectric structure, the method may further include removing the first filling structure and the second semiconductor material layer to expose the second active structure.

It can be understood that the second semiconductor material layer covers the surfaces of the first filling structure, the first semiconductor material layer and the first active structure, and since the second semiconductor material layer and the first filling structure each is made of a second insulating material (for example, SiN), the thickness of the SiN material on the second surface (i.e. the surface of the second active structure away from the first active structure) of the second active structure is larger than the thickness of the SiN material on the first semiconductor material layer. In this case, the SiN material covered on the first semiconductor material layer and a part of the SiN material on the second surface of the second active structure can be removed by anisotropic etching, and the remaining SiN material coats the surface of the second active structure. Taking the SiN material as an example of the second insulating material, after the isolation dielectric structure is formed, the SiN material coating on the surface of the second active structure is removed, to expose the second active structure, for facilitating subsequent fabrication of the second transistor.

In some possible embodiments, in case where the first active structure, the first intermediate layer and the second active structure are made of the same material and the first filling structure is not formed, the operation of removing a portion, covering the first semiconductor material layer, of the second semiconductor material layer to expose the first semiconductor material layer may include: removing a portion of the second semiconductor material layer covering the first semiconductor material layer and a portion of the second semiconductor material layer covering the second surface of the second active structure, to expose the first semiconductor material layer and the second surface. The second surface is a surface of the second active structure away from the first active structure.

It can be understood that, taking the SiN material as an example of the second insulating material, after a layer of SiN material is deposited (for example, via atomic layer deposition) on the surface of the second active structure and the first semiconductor material layer, the deposited SiN material is a second semiconductor material layer, and the second semiconductor material layer coats the second active structure and covers the first semiconductor material layer. Next, the SiN material on the second surface of the second active structure and on the first semiconductor material layer may be removed by anisotropic etching, and after the etching is completed, the remaining SiN material is located on the side (i.e., the surface of the second active structure except the second surface and the surface in contact with the first intermediate layer) of the second active structure.

In some possible embodiments, in case where the first active structure, the first intermediate layer and the second active structure are made of the same material, and the first filling structure is not formed, the method further comprises: after the first semiconductor material layer is removed to expose the first intermediate layer, depositing a second insulating material on the second surface and the first region of the first surface to form a third semiconductor material layer. The first region is not in contact with the second active structure. After the above-described oxidation treatment is performed on the first intermediate layer to form the isolation dielectric structure, the method may further include: removing the second semiconductor material layer and the third semiconductor material layer to expose the second active structure.

It will be appreciated that, for example, when the second insulating material is SiN material, after removing the first semiconductor material layer, a layer of SiN material is deposited (for example, via physically vapor deposition) on the second surface of the second active structure and on the region (i.e. the first region) of the first surface which is not in contact with the first intermediate layer, to form the third semiconductor material layer. The third semiconductor material layer is not in contact with the first intermediate layer, and while the first intermediate layer is exposed, the second active structure is jointly coated by the third semiconductor material layer and the second semiconductor material layer, so that the second active structure can be protected from being oxidized in a subsequent oxidation treatment. Taking the SiN material as an example of the second insulating material, after the isolation dielectric structure is formed, the SiN material coating on the surface of the second active structure and the first surface of the first transistor is removed, to expose the second active structure, for facilitating subsequent fabrication of the second transistor.

At step S104, a second transistor is formed based on the second active structure. The first transistor and the second transistor are self-aligned in a direction perpendicular to the channel.

It is understood that after the second active structure is formed, other structures (such as a second source-drain structure, a second gate structure, a second metal interconnection layer or the like) in the second transistor may be formed based on the second active structure.

In some possible embodiments, in case where the substrate includes the top substrate, the intermediate sacrificial layer and the bottom substrate that are sequentially disposed and stacked, the above-described step S104 may include: forming second dummy gate structures disposed at intervals on the surface of the second active structure; etching a portion of the second active structure along an extending direction of the second active structure to form a second source-drain structure; depositing a semiconductor material on the second active structure and the second source-drain structure to form a second interlayer dielectric layer; removing the second dummy gate structures to form a second gate structure; removing a portion of the second interlayer dielectric layer to form a second source-drain metal trench; depositing a metal material in the second source-drain metal trench to form a second source-drain metal; performing a back end of line process over the second interlayer dielectric layer and the second gate structure to form a second metal interconnection layer.

In some embodiments, the operation of forming second dummy gate structures disposed at intervals on the surface of the second active structure may include performing photolithography to open a gate region of the second transistor, and depositing a semiconductor material on the gate region of the second transistor to form the second dummy gate structures of the second transistor.

It should be noted that the same semiconductor material or different semiconductor materials may be used for fabricating the first dummy gate structure and the second dummy gate structure, which is not limited in the embodiments of the present disclosure.

In some embodiments, after forming the second dummy gate structure, the above method may further include: depositing an insulating material on both sides of the second dummy gate structure to form a second spacer.

It should be noted that the same insulating material or different insulating materials may be used for fabricating the first spacer and the second spacer, which is not limited in the embodiments of the present disclosure.

In some embodiments, the operation of etching a portion of the second active structure along an extending direction of the second active structure to form a second source-drain structure may include: etching to remove a portion of the second active structure, which may provide a source-drain trench of the second transistor; with taking the second spacer as a mask, forming a strain material such as silicon germanium or silicon carbide in the source-drain trench of the second transistor by selective epitaxial growth to fill the source-drain trench of the second transistor; and forming a second source-drain structure on the strain material by a heavy doping process.

In some embodiments, the operation of depositing a semiconductor material on the second active structure and the second source-drain structure to form a second interlayer dielectric layer may include: depositing an insulating material over the second active structure and the second source-drain structure to form a second interlayer dielectric layer. The second interlayer dielectric layer may cover the second active structure and the second source-drain structure.

It should be noted that the same semiconductor material or different semiconductor materials may be used for fabricating the first interlayer dielectric layer and the second interlayer dielectric layer, which is not limited in the embodiments of the present disclosure.

In some embodiments, the operation of removing the second dummy gate structures to form a second gate structure may include: etching to remove the second dummy gate structures, to expose a gate region of the second transistor; and depositing a metal material on the gate region of the second transistor to form the second gate structure of the second transistor.

It should be noted that the same metal material or different metal materials may be used for fabricating the first gate structure and the second gate structure, which is not limited in the embodiments of the present disclosure.

In some embodiments, before fabricating the second gate structure, the above method may further include: depositing a semiconductor material on a surface of the second active structure to form a second gate dielectric layer of the second transistor. The second gate dielectric layer is used to isolate the second active structure and the second gate structure.

It should be noted that the same semiconductor material or different semiconductor materials may be used for fabricating the first gate dielectric layer and the second gate dielectric layer, which is not limited in the embodiments of the present disclosure.

In some embodiments, the operation of removing a portion of the second interlayer dielectric layer to form a second source-drain metal trench and depositing a metal material in the second source-drain metal trench to form a second source-drain metal may include: etching a partial region of the second interlayer dielectric layer located above the second source-drain structure until an upper surface of the second source-drain structure is exposed, to form the second source-drain metal trench; and depositing a metal material in the second source-drain metal trench to obtain a second source-drain metal.

In some embodiments, the operation of performing a back end of line process over the second interlayer dielectric layer and the second gate structure to form a second metal interconnection layer may include: performing processing such as interconnected-line dielectric deposition, metal line formation, bonding pad formation and the like on the second interlayer dielectric layer, to form the second metal interconnection layer of the second transistor.

In some possible embodiments, in case where the first active structure, the first intermediate layer and the second active structure are made of the same material, before the above step S104, the method may further include: depositing a first insulating material on a first surface of the first transistor facing the second active structure to form a first semiconductor material layer, where the first semiconductor material layer surrounds the first intermediate layer; depositing a second insulating material on the second active structure and the first semiconductor material layer to form a second semiconductor material layer, where the second semiconductor material layer coats the second active structure; removing a portion of the second semiconductor material layer covering the first semiconductor material layer to expose the first semiconductor material layer; and removing the first semiconductor material layer to expose the first intermediate layer.

It can be understood that the first transistor and the second transistor are disposed oppositely each other, and in the fabrication process, the first transistor is fabricated first, and the first transistor is flipped after the fabrication of the first transistor is completed, and a first insulating material is deposited above (i.e., on the first surface of the first transistor close to the second transistor) the first transistor to form a first semiconductor material layer. A second insulating material is deposited using an atomic layer deposition method on the second active structure and the first semiconductor material layer, and the formed second semiconductor material layer may cover the first semiconductor material layer while coating the second active structure. In the subsequent fabrication process, it is necessary to expose the first intermediate layer, and according to the order in which the material layers are stacked, the portion of the second semiconductor material layer covered on the first semiconductor material layer (that is, the portion of the second semiconductor material layer covering the first semiconductor material layer) is removed, to expose the first semiconductor layer, for facilitating the subsequent removal of the first semiconductor material layer.

In some embodiments, the first semiconductor material layer covers the first surface and surrounds the first intermediate layer.

In some embodiments, the first insulating material may include, but is not limited to, amorphous carbon and amorphous silicon, and may be other insulating materials, which is not limited in the embodiments of the present disclosure.

In some embodiments, the second insulating material and the first insulating material are different insulating materials, and for convenience of explanation, silicon nitride (SiN) is taken as an example of the second insulating material. It should be noted that the second insulating material may be another insulating material, which is not limited in the embodiment of the present disclosure.

In some embodiments, the second semiconductor material layer coats the second active structure and covers the first semiconductor material layer.

In some possible embodiments, in case where the first active structure, the first intermediate layer and the second active structure are made of the same material, the above method may further include before the above step S104: removing a portion of the second semiconductor material layer covering the second active structure to expose the second active structure.

It can be understood that in the above-described process of removing a part of the second semiconductor material layer covering the first semiconductor material layer to expose the first semiconductor material layer, the second semiconductor material layer is not completely removed, and a part of the second semiconductor material layer surrounds the surface of the second active structure. After this part of the second semiconductor material layer is removed, the second active structure can be exposed, for facilitating subsequent fabrication of the second transistor.

In some possible embodiments, in case where the first active structure, the first intermediate layer and the second active structure are made of the same material, the above step S104 may include sequentially forming a second dummy gate structure, a second spacer, a second source-drain structure and a second interlayer dielectric layer of the second transistor based on the second active structure; removing the second dummy gate structure and forming a second gate structure and a second gate dielectric layer; and performing a back end of line process on the second interlayer dielectric layer to form a second metal interconnection layer.

It should be noted that when the first active structure, the first intermediate layer and the second active structure are made of the same material, the process of fabricating the second transistor is the same as the process of fabricating the first transistor described above.

At step S105, an isolation dielectric structure is formed based on the first intermediate layer. The material of the isolation dielectric structure is different from the material of the first intermediate layer. The isolation dielectric structure is used to isolate the first active structure and the second active structure.

It will be appreciated that during the fabrication of the stacked transistor, the material of the first intermediate layer may be replaced to form the isolation dielectric structure; The material of the isolation dielectric structure is different from the material of the first intermediate layer.

In some possible embodiments, in case where the substrate includes the top substrate, the intermediate sacrificial layer and the bottom substrate that are sequentially disposed and stacked, the above-described step S105 may include: after forming the first dummy gate structure, removing the first intermediate layer to form a first gap; filling an insulation material in the first gap to form an isolation dielectric structure. The isolation dielectric structure is used to isolate the first active structure and the second active structure.

It will be appreciated that the first intermediate layer located between the first active structure and the second active structure may be selectively removed to form a first gap. In the process of selective removal, the first dummy gate structure may provide structural support to the first active structure so that the position of the first active structure in the first transistor does not change, and the first active structure and the second active structure still maintain self-alignment. By filling the first gap with the insulation material, such as a low dielectric constant (low K) material, an isolation dielectric structure may be formed, and the isolation dielectric structure may achieve electrical isolation between the first transistor and the second transistor by isolating the first active structure and the second active structure.

In some embodiments, after forming the first dummy gate structure, an insulation material may be deposited on both sides of the first dummy gate structure to form a first spacer. It should be noted that the first spacer and the isolation dielectric structure may be fabricated simultaneously.

In some possible embodiments, in case where the substrate includes the top substrate, the intermediate sacrificial layer and the bottom substrate that are sequentially disposed and stacked, the above-described step of forming a first dummy gate structure and a first shallow trench isolation structure that surrounds the second active structure disposed at intervals on the surface of the first active structure may include: forming a second shallow trench isolation structure that surrounds the first active structure, the first intermediate layer and the second active structure; removing a portion of the second shallow trench isolation structure to expose the first active structure and the first intermediate layer, to form the first shallow trench isolation structure; and forming a first dummy gate structure based on the first active structure.

It will be appreciated that the second shallow trench isolation structure coats the entire active structure, and a portion of the second shallow trench isolation structure may be etched to be removed, to expose the first active structure and the first intermediate layer. For ease of distinguishing, the etched second shallow trench isolation structure may be referred to as a first shallow trench isolation structure. The first shallow trench isolation structure coats the second active structure. Next, a semiconductor material, such as poly Si, is deposited on the gate region of the first transistor to form a first dummy gate structure of the first transistor.

It should be noted that the etching process mentioned in the embodiments of the present disclosure may include, but is not limited to, any one of the following: dry etching, wet etching, reactive ion etching and chemical oxide removal process, which is not limited in the embodiments of the present disclosure.

In some embodiments, the solvent used to etch the second shallow trench isolation structure may be a Dilute Hydrofluoric acid (DHF) solution (including hydrofluoric acid (HF), the hydrogen peroxide (H₂O₂), and water (H₂O)) or a buffer oxide etching (BOE) solution. The solvent used in the etching of the embodiment of the present disclosure can be selected according to the actual situation, and is not limited to the above-described DHF solution or BOE solution.

In some embodiments, a method of forming the first dummy gate structure may include opening a gate region of the first transistor by photolithography and depositing a semiconductor material on the gate region of the first transistor to form a first dummy gate structure of the first transistor.

It will be appreciated that the first dummy gate structure is connected to the first shallow trench isolation structure at the first intermediate layer.

In some possible embodiments, in case where the first active structure, the first intermediate layer and the second active structure are made of the same material, the above-described step S105 may include: performing an oxidation treatment on the first intermediate layer to form an isolation dielectric structure.

As can be understood, after the oxidation treatment, the material of the first intermediate layer is oxidized to be a different material from the first active structure and the second active structure, and the first intermediate layer is transformed into the isolation dielectric structure. The isolation dielectric structure may be used to isolate the first active structure and the second active structure due to the difference in materials.

In some embodiments, since the isolation dielectric structure is located between the first active structure and the second active structure, and the material of the isolation dielectric structure formed by the oxidation treatment is different from the material of the first active structure and the second active structure, the isolation dielectric structure can isolate the active region of the first transistor from the active region of the second transistor.

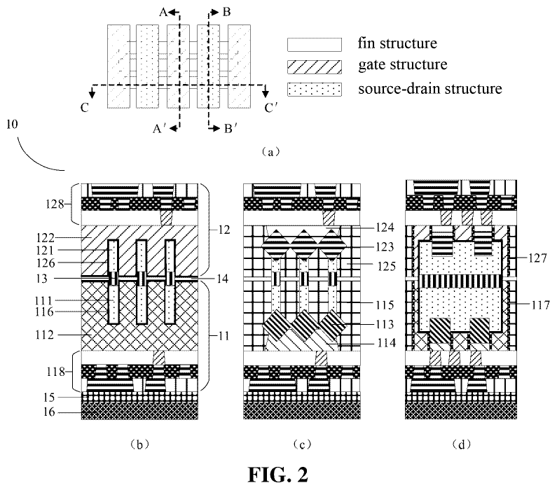

Hereinafter, the stacked transistor provided in an embodiment of the present disclosure will be described by taking the fin-shaped field effect transistor as the first transistor and the second transistor and taking a case that the substrate includes a top substrate, an intermediate sacrificial layer and a bottom substrate that are disposed and stacked in sequence as an example. FIG. 2 is a first schematic structural diagram of a stacked transistor according to an embodiment of the present disclosure. In FIG. 2, (a) shows a design layout of the stacked transistor. It should be noted that only a fin structure, a gate structure and a source-drain structure are shown in the design layout for convenience of understanding; (b) shows a cross-sectional view of the stacked transistor taken along the cross-sectional direction (i.e., the A-A′ direction) of the gate structure; (c) shows a cross-sectional view of the stacked transistor taken along the cross-sectional direction (i.e. B-B′ direction) of the source-drain structure; (d) shows a cross-sectional view of the stacked transistor taken along the cross-sectional direction (i.e., the C-C′ direction) of the fin structure.

Referring to FIG. 2, the stacked transistor 10 includes a first transistor 11 and a second transistor 12, and the active structure in the stacked transistor 10 includes a plurality of fin structures. The fin structure is divided into upper and lower parts, denoted as a first part and a second part, respectively. The first part serves as the first active structure 111 in the first transistor 11, and the second part serves as the second active structure 121 in the second transistor 12. An isolation dielectric structure 13 is provided between the first active structure 111 and the second active structure 121, and the isolation dielectric structure 13 is used to isolate the first active structure 111 and the second active structure 121.

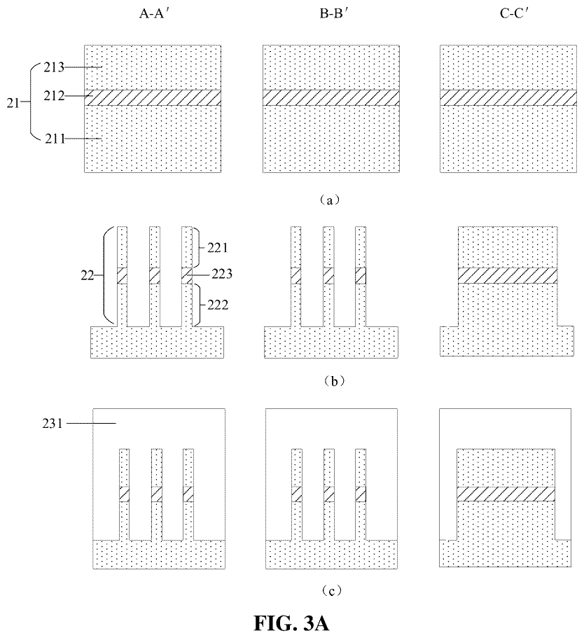

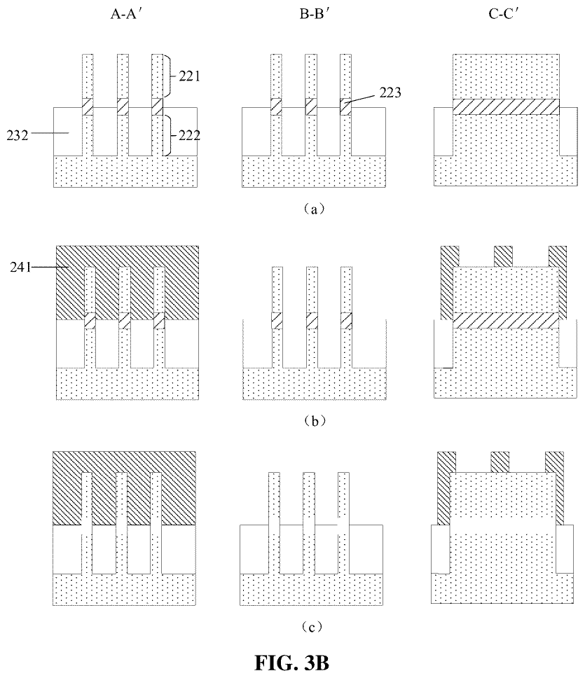

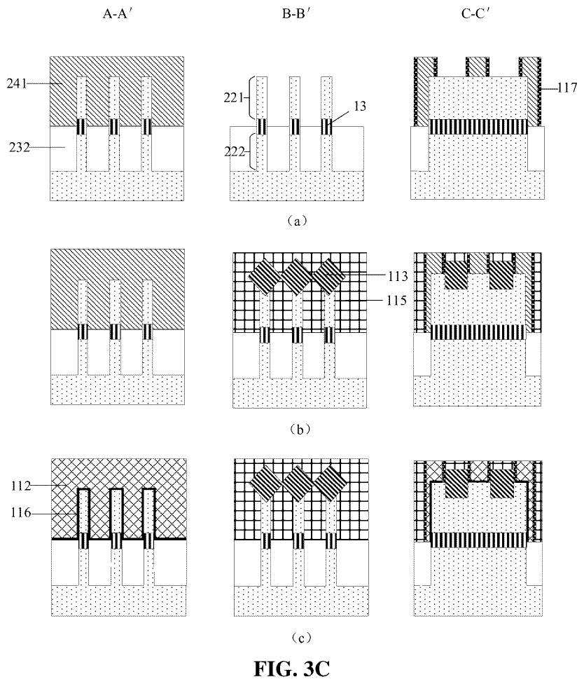

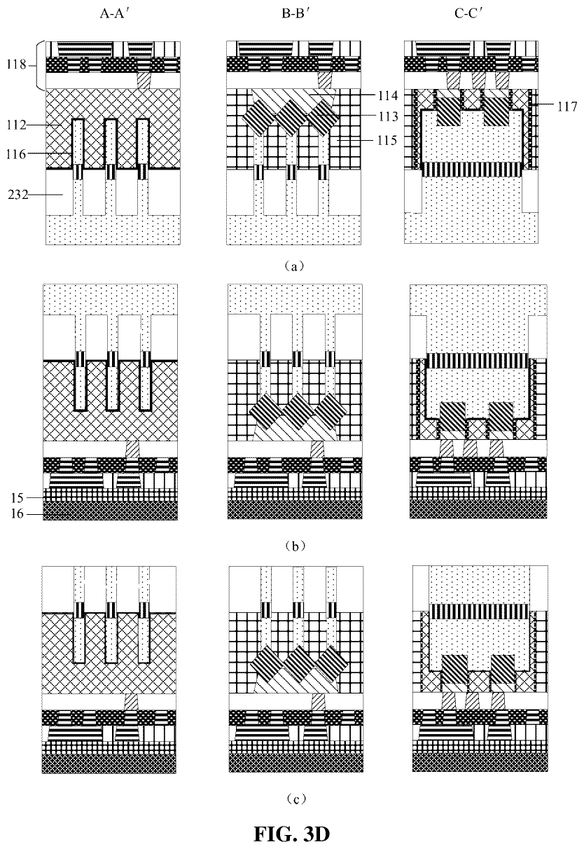

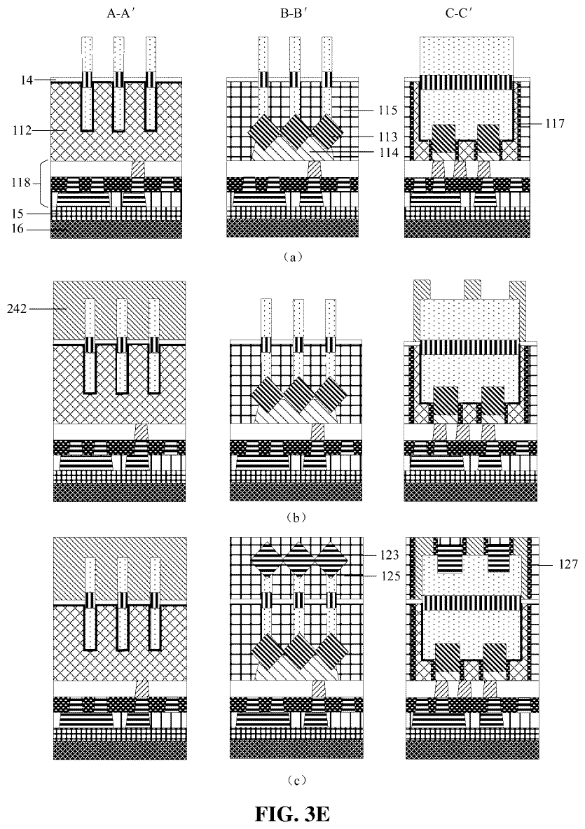

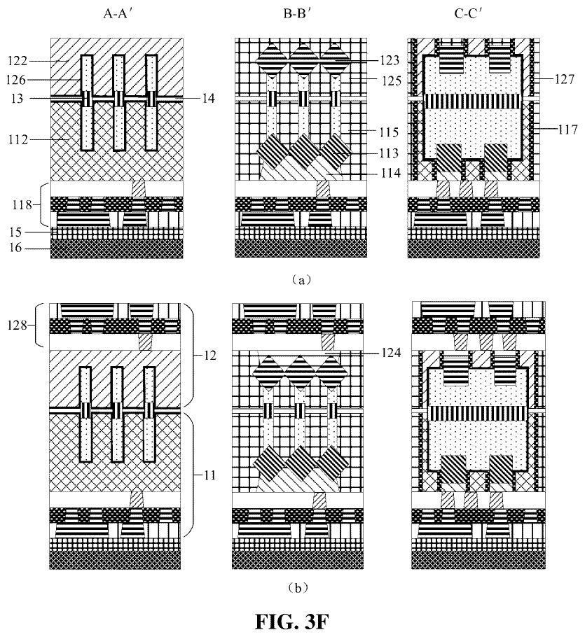

Hereinafter, a fabrication process of the stacked transistor 10 shown in FIG. 2 will be described in conjunction with the above-described fabrication method. The stacked transistor 10 shown in FIG. 2 can be fabricated by the flows shown in FIGS. 3A to 3F, which are schematic diagrams of a first fabrication process of a stacked transistor provided according to an embodiment of the present disclosure.

In an example, taking the fin-shaped field effect transistor as an example of the first transistor 11 and the second transistor 12, the first fabrication process of the stacked transistor 10 may include the following steps.

At the first step, a bottom substrate 211 (e.g., Si substrate) is provided. A layer of silicon germanium material is epitaxially applied on the bottom substrate 211 as an intermediate sacrificial layer 212. The Si material is then epitaxially applied on the intermediate sacrificial layer 212 to form a top substrate 213 (see (a) in FIG. 3A).

In some embodiments, the bottom substrate 211, the intermediate sacrificial layer 212 and the top substrate 213 collectively constitute the substrate 21.

At the second step, the top substrate 213, the intermediate sacrificial layer 212 and the bottom substrate 211 are sequentially etched to form a plurality of fin structures 22 (see (b) in FIG. 3A).

In some embodiments, the height of the fin structure 22 is greater than 100 nm.

At the third step, the oxide is filled above the fin structures 22 to form a second shallow trench isolation structure 231, and a chemical mechanical planarization process is performed on the second shallow trench isolation structure 231 (see (c) in FIG. 3A).

In some embodiments, the height of the second shallow trench isolation structure 231 is greater than the height of the fin structure 22, and may cover the multiple fin structures 22.

At the fourth step, a portion of the second shallow trench isolation structure 231 is etched until the first fin structures 221 and the first intermediate layer 223 are exposed (see (a) in FIG. 3B).

In some embodiments, the second shallow trench isolation structure 231 after the etching coats the second fin structure 222, and the second shallow trench isolation structure 231 after the etching may be referred to as the first shallow trench isolation structure 232 for distinction.

At the fifth step, a gate region of the first transistor 11 is opened through photolithography, and polysilicon is deposited at the gate region of the first transistor 11 to form the first dummy gate structures 241 (see (b) in FIG. 3B).

In some embodiments, the first dummy gate structures 241 span cross the first fin structures 221 and are disposed at intervals on the surface of the first fin structure 221.

At the sixth step, the first intermediate layer 223 is selectively removed to form a first gap (see (c) in FIG. 3B).

In some embodiments, the first dummy gate structure 241 provides structural support for the first fin structures 221 when the first intermediate layer 223 is removed.

At the seventh step, the first gap is filled with low K material to form the isolation dielectric structure 13. Also, first spacers 117 are formed on both sides of the first dummy gate structure 241 (see (a) in FIG. 3C).

At the eighth step, a part of the fin structure is etched to form a source-drain trench of the first transistor 11, and the first source-drain structure 113 is formed by source-drain epitaxial growth at the source-drain trench of the first transistor 11. Then, a semiconductor material is deposited over the first fin structure 221 to form a first interlayer dielectric layer 115 (see (b) in FIG. 3C).

At the ninth step, the first dummy gate structures 241 are removed, and an insulating material is deposited on the surface of the first fin structure 221 to form a first gate dielectric layer 116, and metal is deposited on the gate region of the first transistor 11 to form a first gate structure 112 (see (c) in FIG. 3C).

At the tenth step, a first source-drain metal 114 is fabricated over the first source-drain structure 113, and a back end of line process is performed on the first interlayer dielectric layer 115 to form a first metal interconnection layer 118 (see (a) in FIG. 3D).

At the eleventh step, the oxide is deposited over the first metal interconnection layer 118 to form a first insulating layer 15. The first insulating layer 15 is then bonded to a carrier wafer 16. Next, the first transistor 11 bonded to the carrier wafer 16 is flipped, so that the bottom substrate 211 is placed upward (see (b) in FIG. 3D).

At the twelfth step, a wafer thinning process and a CMP process are adopted to remove the bottom substrate 211 until the bottom of the fin structure 22 is exposed (see (c) in FIG. 3D).

At the thirteenth step, the first shallow trench isolation structure 232 is selectively etched until the second fin structure 222 is exposed (see (a) in FIG. 3E).

In some embodiments, the first shallow trench isolation structure 232 of a certain thickness is retained as the shallow trench isolation layer 14, and the shallow trench isolation layer 14 is used to isolate the first gate structure 112 and the second gate structure 122.

At the fourteenth step, a gate region of the second transistor 12 is opened through photolithography, and polysilicon is deposited at the gate region of the second transistor 12 to form a second dummy gate structure 242 (see (b) in FIG. 3E).

At the fifteenth step, a second spacer 127, a second source-drain structure 123 and a second interlayer dielectric layer 125 of the second transistor 12 are formed (referring to the seventh and eighth steps for the fabrication process) (see (c) in FIG. 3E).

At the sixteenth step, a second gate structure 122 of the second transistor 12 is formed. (referring to Step 9 for the fabrication process).

At the seventeenth step, a second source-drain metal 124 and a second metal interconnection layer 128 of the second transistor 12 are formed (referring to the tenth step for the fabrication process).

Thus, the stacked transistor 10 in which the first transistor 11 and the second transistor 12 are fin-shaped field effect transistors are fabricated.

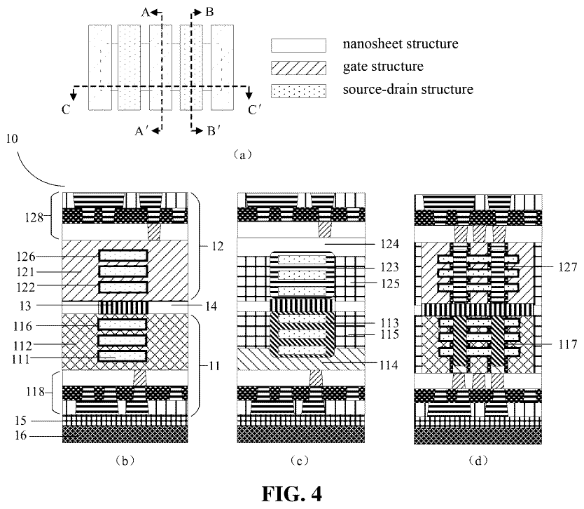

Hereinafter, a stacked transistor provided in an embodiment of the present disclosure will be described by taking the nanosheet field effect transistors as an example of the first transistor and the second transistor, and the substrate includes a top substrate, an intermediate sacrificial layer and a bottom substrate that are disposed and stacked in sequence as an example. FIG. 4 is a second schematic structural diagram of a stacked transistor provided according to an embodiment of the present disclosure. In FIG. 4, (a) shows a design layout of the stacked transistor, and it should be noted that only the nanosheet structure, the gate structure and the source-drain structure are shown in the design layout for convenience of understanding; (b) shows a cross-sectional view of the stacked transistor taken along the cross-sectional direction (i.e., the A-A′ direction) of the gate structure; (c) shows a cross-sectional view of the stacked transistor taken along the cross-sectional direction (i.e. B-B′ direction) of the source-drain structure; (d) shows a cross-sectional view of the stacked transistor taken along the cross-sectional direction (i.e., the C-C′ direction) of the nanosheet structure.

Referring to FIG. 4, the stacked transistor 10 includes a first transistor 11 and a second transistor 12, and the active structure in the stacked transistor 10 includes a plurality of nanosheet structures. The nanosheet structure is divided into upper and lower parts, denoted as a first part and a second part, respectively. The first part serves as the first active structure 111 in the first transistor 11, and the second part serves as the second active structure 121 in the second transistor 12. An isolation dielectric structure 13 is provided between the first active structure 111 and the second active structure 121, and the isolation dielectric structure 13 is used to isolate the first active structure 111 and the second active structure 121.

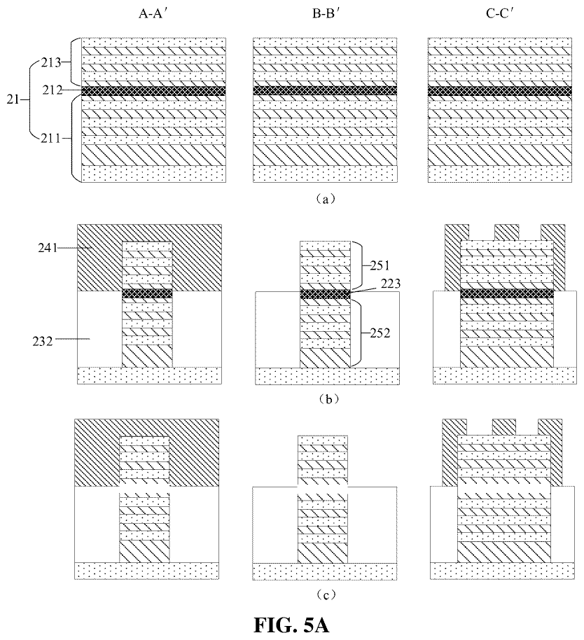

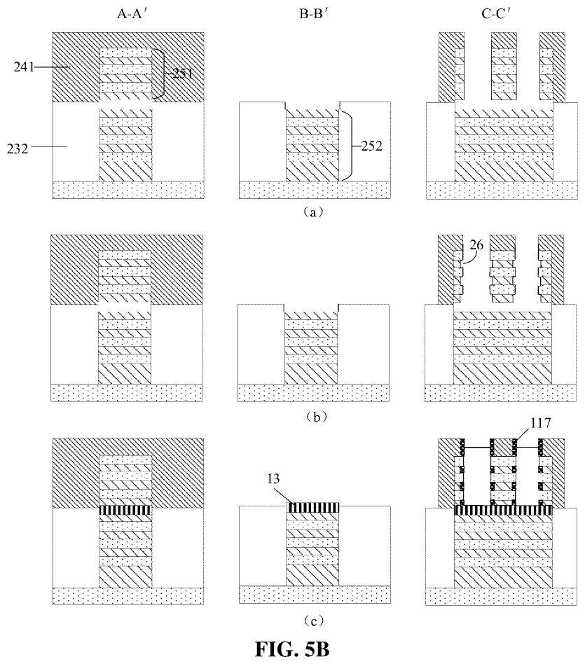

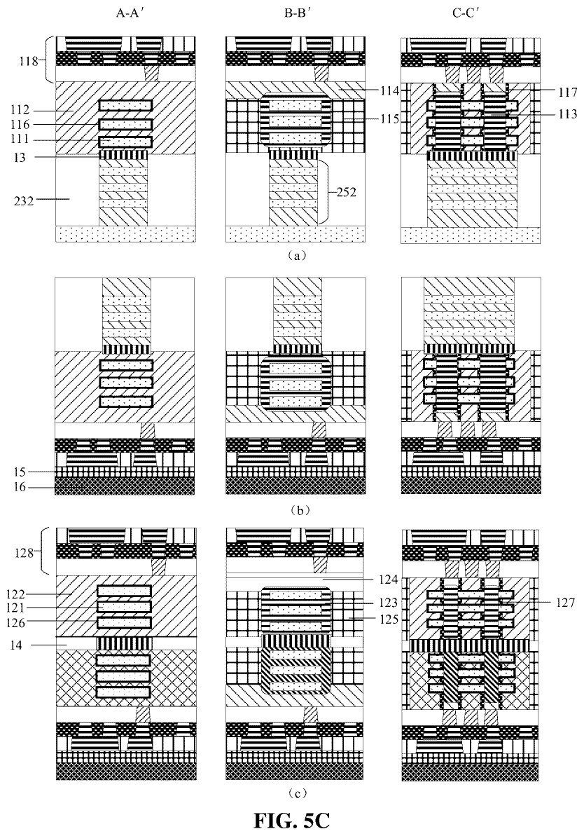

Hereinafter, a fabrication process of the stacked transistor 10 shown in FIG. 4 will be described in conjunction with the above-described fabrication method. The stacked transistor 10 shown in FIG. 4 can be fabricated by the flows shown in FIGS. 5A to 5C, which are schematic diagrams of a second fabrication process of a stacked transistor provided according to an embodiment of the present disclosure.

In an example, taking the nanosheet field effect transistor as an example of the first transistor 11 and the second transistor 12, the second fabrication process of the stacked transistor 10 may include the following steps.

At the first step, a bottom substrate 211 is provided. The bottom substrate 211 is a stacked layer formed by alternately depositing a Si material and a SiGe 1 material in sequence (i.e., a stacked layer composed of Si layer and SiGe 1 layer). A SiGe 2 material is deposited on the bottom substrate 211 as an intermediate sacrificial layer 212. A Si material and a SiGe 1 material are alternately deposited sequentially on the intermediate sacrificial layer 212 to form a top substrate 213 (see (a) in FIG. 5A).

In some embodiments, in order to facilitate subsequent selective etching, the concentration of Ge in the SiGe 1 material is different from that in the SiGe 2 material.

In some embodiments, the above-described deposited SiGe 2 material is only an example of the intermediate sacrificial layer 212, and other semiconductor materials may be used to fabricate the intermediate sacrificial layer 212, or other forms of material layers (such as stacked layers) may be used to fabricate the intermediate sacrificial layer, which is not limited in the embodiments of the present disclosure. The Si material, the SiGe 2 material and the Si material are alternately deposited sequentially to form a stacked layer as the intermediate sacrificial layer 212. The stacked layer formed by the Si material, SiGe 2 material and Si material can improve a etching selectivity ratio.

At the second step, the top substrate 213, the intermediate sacrificial layer 212 and the bottom substrate 211 are etched sequentially to form the pillar structure 25. The oxide is filled above the pillar structure 25 to form a second shallow trench isolation structure 231. Then, a chemical mechanical planarization process is performed on the second shallow trench isolation structure 231. A portion of the second shallow trench isolation structure 231 is etched until a first portion 251 of the pillar structure and the first intermediate layer 223 are exposed to form the first shallow trench isolation structure 232. Next, the first dummy gate structures 241 are formed (see (b) in FIG. 5A) (referring to the fifth step of the first fabrication process of the stacked transistor for the process).

At the third step, the first intermediate layer 223 is selectively removed to form a first gap (see (c) in FIG. 5A).

At the fourth step, a part, located in a first source-drain region of the first transistor 11, in the first portion 251 of the pillar structure is selectively removed, to expose the first source-drain region for subsequent fabrication of the first source-drain structure 113 (see (a) in FIG. 5B).

At the fifth step, the layer of SiGe 1 material at the junction of the first portion 251 (i.e. the upper half of the stacked layer) of the pillar structure and the first source-drain region is etched to form a first inner side wall 26 (see (b) in FIG. 5B).

At the sixth step, the first gap is filled with low K material to form the isolation dielectric structure 13, and the low K material is filled inside the first inner side wall 26 to isolate the SiGe 1 material layer from the first source-drain structure 113. Also, first spacers 117 are formed on both sides of the first dummy gate structure 241 (see (c) in FIG. 5B).

At the seventh step, a first source-drain structure 113, a first interlayer dielectric layer 115, a first gate structure 112, a first gate dielectric layer 116 and a first metal interconnection layer 118 are formed (see (a) in FIG. 5C) (for the process, referring to the eighth to tenth steps of the first fabrication process of the stacked transistor).

At the eighth step, after flipping, the bottom substrate 211 is removed until an upper surface of a second portion 252 of the pillar structure is exposed (see (b) in FIG. 5C) (for the process, referring to the eleventh and twelfth steps of the first fabrication process of the stacked transistor).

At the ninth step, a second transistor is formed according to a standard process (see (c) in FIG. 5C) (for the process, referring to the thirteen to seventeenth steps of the first fabrication process of the stacked transistor).

Thus, the stacked transistor 10 in which the first transistor 11 and the second transistor 12 are nanosheet field effect transistors are fabricated.

In some embodiments, when the first transistor and the second transistor are planar transistors or vertical field effect transistors, except that the active structure is different from the active structure of the stacked transistor composed of the fin-shaped field effect transistor and the active structure of the stacked transistor composed of the nanosheet field effect transistor, other structures are the same as those in the stacked transistor composed of the fin-shaped field effect transistor and the stacked transistor composed of the nanosheet field effect transistor. Accordingly, except that the fabrication process of the active structure is different, the fabrication process of the other structures is the same as the preparation process shown in the above example.

Electrical isolation between the first active structure and the second active structure is realized by the isolation dielectric structure in the embodiments of the present disclosure. Compared with the isolation method in which an SOI substrate is used and ion implantation is performed between the first active structure and the second active structure, the fabrication cost and the process difficulty can be reduced.

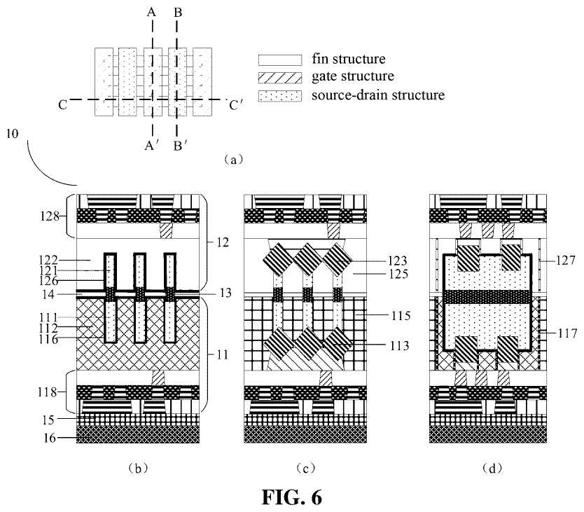

Hereinafter, a stacked transistor provided by an embodiment of the present disclosure will be described by taking a case that the first transistor and the second transistor are the fin-shaped field effect transistors, and the first active structure, the first intermediate layer and the second active structure are made of the same material as an example. FIG. 6 is a third schematic structural diagram of a stacked transistor according to an embodiment of the present disclosure. In FIG. 6, (a) shows a design layout of the stacked transistor, and it should be noted that only the fin structure, the gate structure and the source-drain structure are shown in the design layout for convenience of understanding; (b) shows a cross-sectional view of the stacked transistor taken along the cross-sectional direction (i.e., the A-A′ direction) of the gate structure; (c) shows a cross-sectional view of the stacked transistor taken along the cross-sectional direction (i.e. B-B′ direction) of the source-drain structure; (d) shows a cross-sectional view of the stacked transistor taken along the cross-sectional direction (i.e., the C-C′ direction) of the fin structure.

Referring to FIG. 6, the stacked transistor 10 includes a first transistor 11, a second transistor 12 and an isolation dielectric structure 13. A first active structure 111 of the first transistor 11 and a second active structure 121 of the second transistor 12 are formed by the same process, and the first transistor 11 and the second transistor 12 are self-aligned. The isolation dielectric structure 13 is used to isolate the first active structure 111 and the second active structure 121, and the isolation dielectric structure 13 is located between the first active structure 111 and the second active structure 121.

In some embodiments, since the first active structure 111 of the first transistor 11 and the second active structure 121 of the second transistor 12 are formed by the same etching process, self-alignment of the first transistor 11 and the second transistor 12 can be realized.

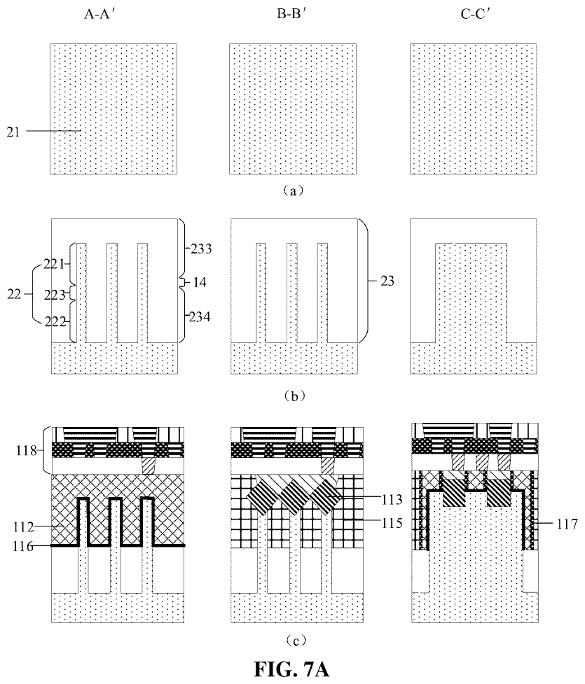

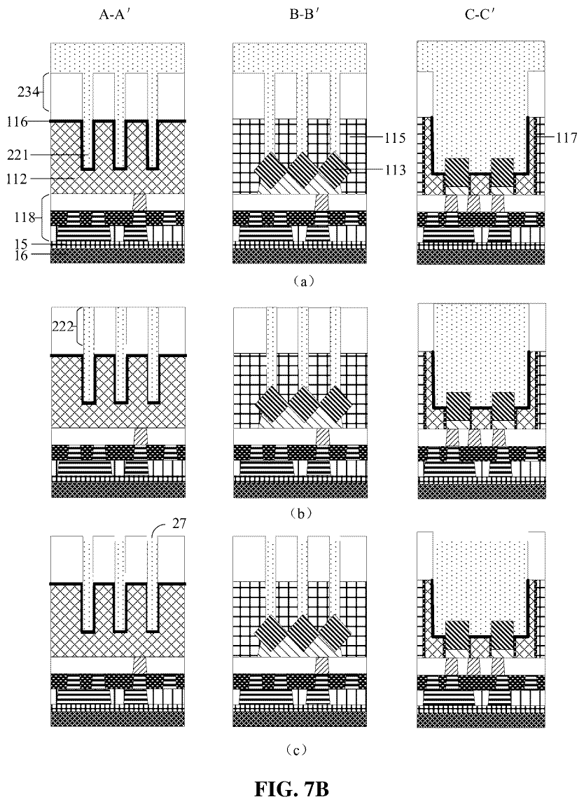

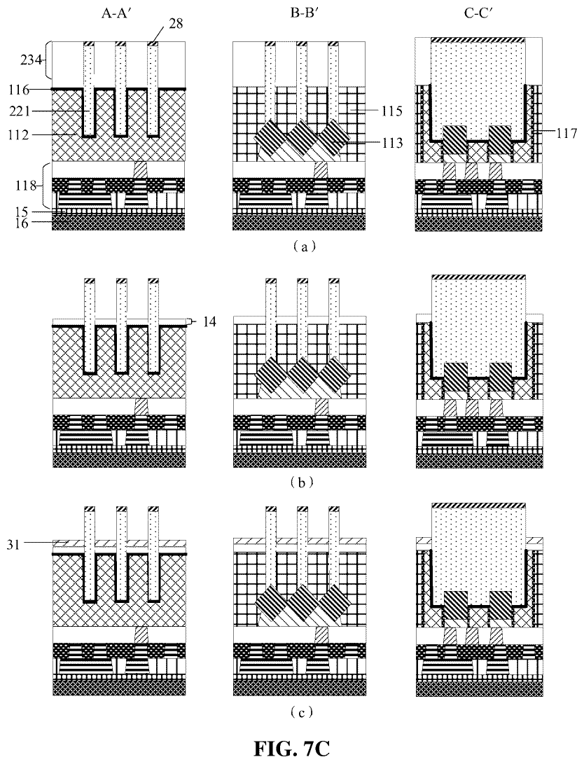

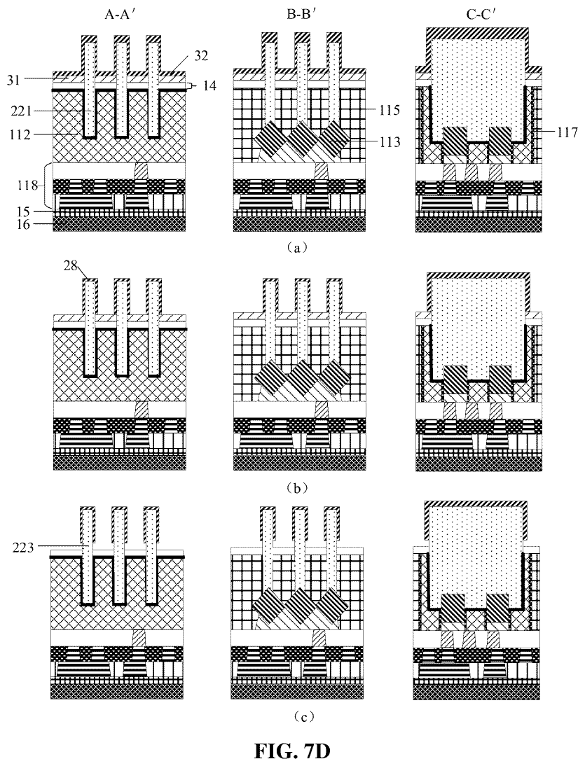

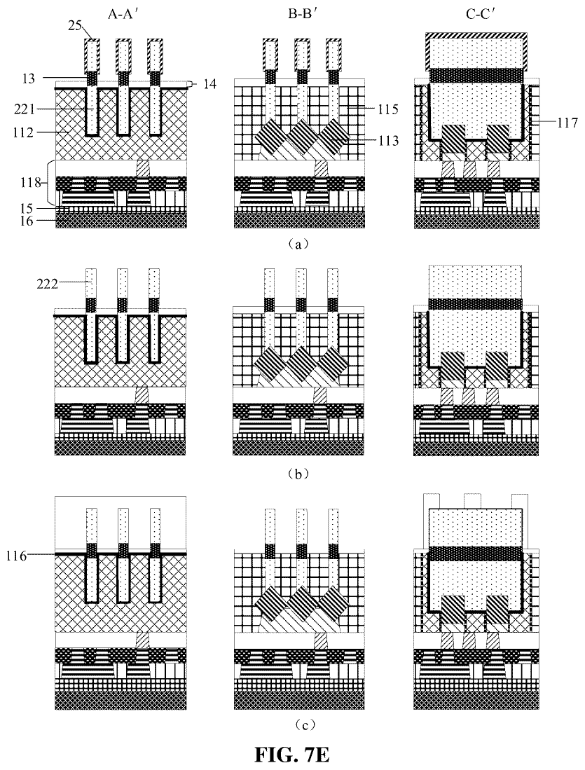

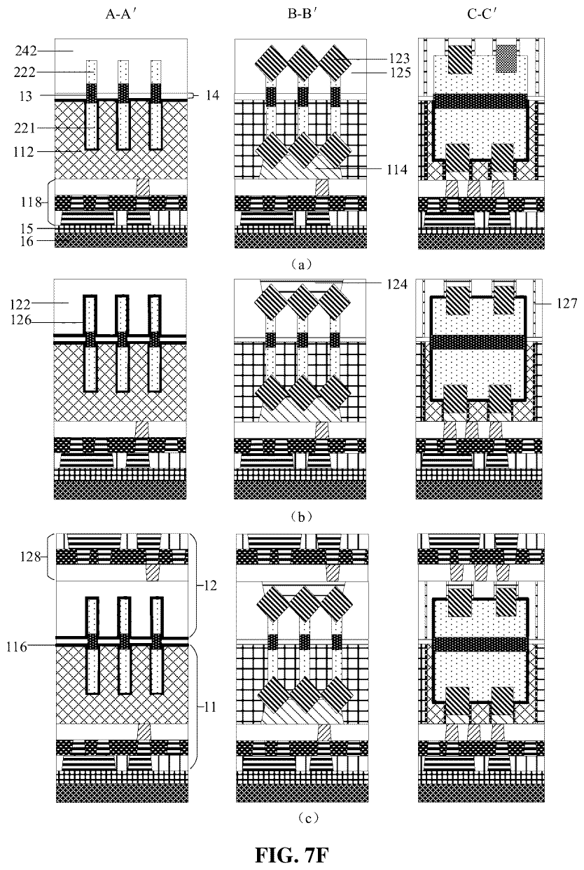

Hereinafter, a fabrication process of the stacked transistor shown in FIG. 6 will be described in conjunction with the above fabrication method. The stacked transistor shown in FIG. 6 can be fabricated by the flows shown in FIGS. 7A to 7F, which are schematic diagrams of a third fabrication process of the stacked transistor provided by an embodiment of the present disclosure.

In an example, the fin-shaped field effect transistor is taken as an example of the first transistor 11 and the second transistor 12, and the first active structure, the first intermediate layer and the second active structure are made of the same material, the third preparation process of the stacked transistor 10 may include the following steps.

At the first step, a substrate 21 (e.g., Si substrate) is provided (see (a) in FIG. 7A).

At the second step, the substrate 21 is etched to form a plurality of fin structures 22, and a dielectric material is deposited on the plurality of fin structures 22 to form a shallow trench isolation structure 23 (see (b) in FIG. 7A).

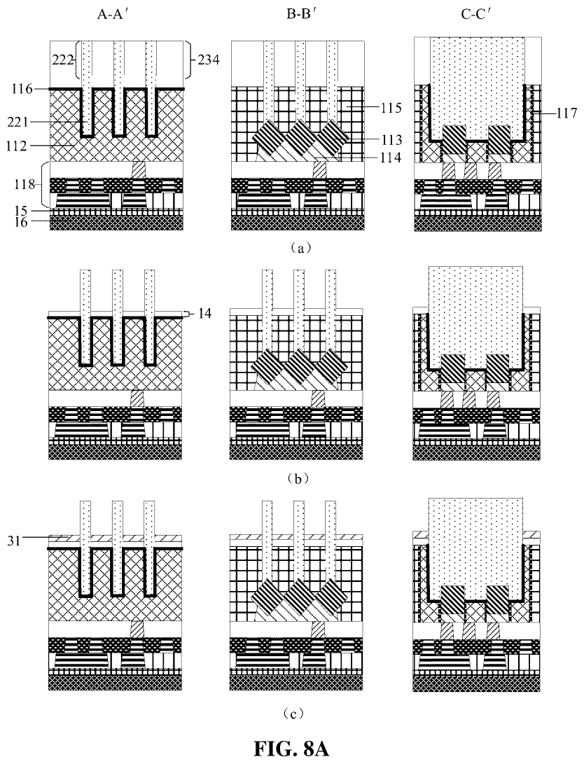

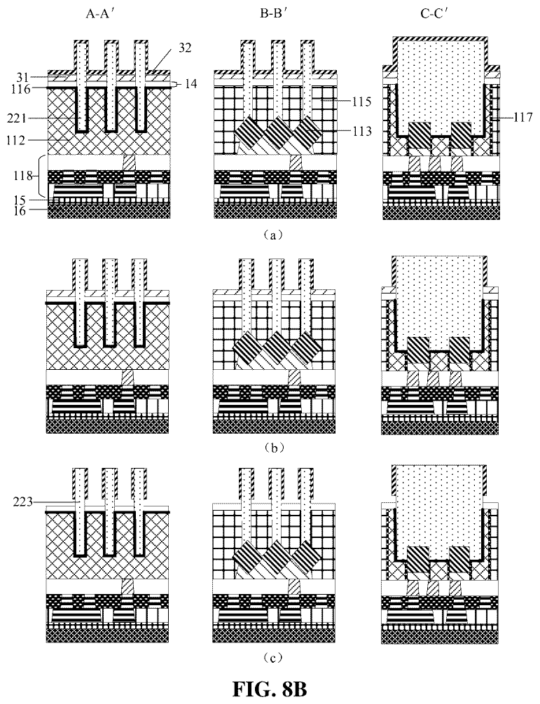

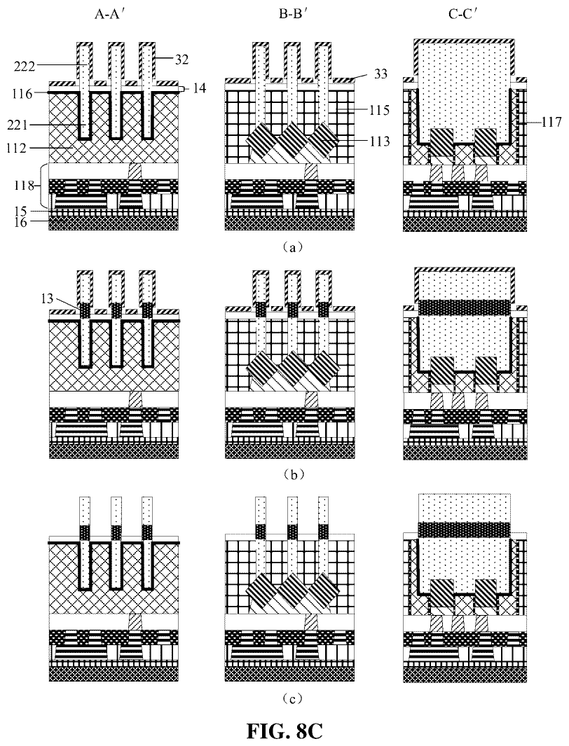

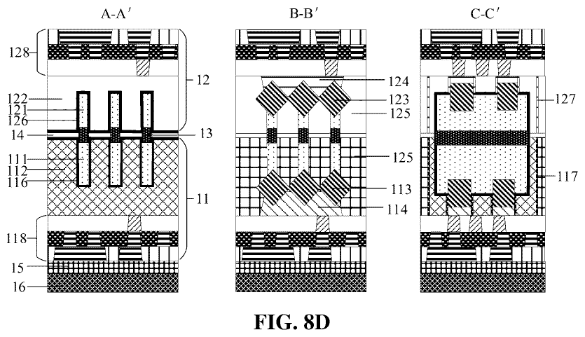

In some embodiments, referring to (b) in FIG. 8A, the fin structure 22 consists of a first fin structure 221, a second fin structure 222 and a first intermediate layer 223. The shallow trench isolation structure 23 is composed of a third shallow trench isolation structure 233, a fourth shallow trench isolation structure 234, and a shallow trench isolation layer 14.

At the third step, the third shallow trench isolation structure 233 is removed to expose the first fin structure 221. Next, a first dummy gate structure, a first spacer 117, a first source-drain structure 113 and a first interlayer dielectric layer 115 in the first transistor 11 are sequentially formed according to the standard procedure. After the first dummy gate structure is removed, a first gate dielectric layer 116, a first gate structure 112, and a first metal interconnection layer 118 are formed (see (c) in FIG. 7A).

At the fourth step, the Oxide is deposited over the first metal interconnection layer 118 to form a first insulating layer 15, which is bonded to the carrier wafer 16. Next, the first transistor 11 which is bonded to the carrier wafer 16 is flipped, so that the substrate 21 is placed upward (see (a) in FIG. 7B).

At the fifth step, a wafer thinning process is performed on the substrate 21 until the substrate 21 is removed, to expose the surface of the second fin structure 222 away from the first fin structure 221 (see (b) in FIG. 7B).

At the sixth step, a portion of the second fin structure 222 is removed by selective etching to form the first trench 27 (see (c) in FIG. 7B).

At the seventh step, the SiN material (not shown in the drawings) is deposited in the first trench 27 and on the fourth shallow trench isolation structure 234, the CMP process is performed the deposited SiN material, and the CMP process is stopped to the surface of the fourth shallow trench isolation structure 234. After the CMP process, a first filling structure 28 is formed (see (a) in FIG. 7C).

At the eighth step, the fourth shallow trench isolation structure 234 is etched to be removed, to expose the second fin structure 222 and the shallow trench isolation layer 14 (see (b) in FIG. 7C).

In some embodiments, the shallow trench isolation layer 14 is used to isolate the first transistor 11 and the second transistor 12.

At the ninth step, amorphous carbon is deposited on the shallow trench isolation layer 14 to form a first semiconductor material layer 31 (see (c) in FIG. 7C).

At the tenth step, a layer of SiN material is atomically deposited on the first semiconductor material layer 31 and on the surface of the second fin structure 222 to form the second semiconductor material layer 32. Due to the first filling structure 28, the thickness of the SiN material on the surface of the second fin structure 222 away from the first fin structure 221 is greater than the thickness of the SiN material on the remaining surface (see (a) in FIG. 7D).

At the eleventh step, the SiN material on the surface of the second fin structure 222 away from the first fin structure 221 and on the first semiconductor material layer 31 is removed by anisotropic etching (see (b) in FIG. 7D).

At the twelfth step, the first semiconductor material layer 31 is removed by isotropic etching, to expose the first intermediate layer 223 (see (c) in FIG. 7D).

At the thirteenth step, the first intermediate layer 223 is oxidized to form the isolation dielectric structure 13 (see (a) in FIG. 7E).

At the fourteenth step, the SiN material on the surface of the second fin structure 222 is removed by isotropic etching (see (b) in FIG. 7E).

At the fifteenth step, the second dummy gate structure 242 of the second transistor 12 is formed using standard procedures (see (c) in FIG. 7E).

At the sixteenth step, a second spacer 127, a second source-drain structure 123, and a second interlayer dielectric layer 125 in the second transistor 12 are sequentially fabricated using standard procedures (see (a) in FIG. 7F).

At the seventeenth step, the second dummy gate structure 242 is removed to expose a gate region of the second transistor 12, an insulating material is deposited at the junction of the gate region and the second fin structure 222 to form the second gate dielectric layer 126. A metal material is deposited at the gate region to form a second gate structure 122 (see (b) in FIG. 7F).

At the eighteenth step, a back end of line process is performed on the second interlayer dielectric layer 125 to form the second metal interconnection layer 128 (see (c) in FIG. 7F).

Thus, the stacked transistor 10 in which the first transistor 11 and the second transistor 12 are fin-shaped field effect transistors and the first active structure 111 and the second active structure 121 are isolated by the isolation dielectric structure 13 has been fabricated by the third preparation method described above.

In some embodiments, compared with the conventional ion implantation and the isolation method using silicon-on-insulator (SOI), the process of fabricating the isolation dielectric structure in the embodiments of the present disclosure is simple, and the self-alignment of the first transistor and the second transistor is also taken into account, and the consistency of the active regions of the first transistor and the second transistor is ensured.

The fabrication process shown in FIGS. 7A to 7F described above is only one example of the stacked transistor in the embodiment of the present disclosure. The stacked transistor in the embodiment of the present disclosure can also be fabricated by the flows shown in FIGS. 8A to 8D, which are schematic diagrams of a fourth fabrication process of the stacked transistor provided according to the embodiment of the present disclosure.

In an example, with taking a case that the first transistor and the second transistor are the fin-shaped field effect transistors, and the first active structure, the first intermediate layer and the second active structure are made of the same material as an example, the fourth fabrication process of the stacked transistor 10 may include the following steps.

At the first step, a substrate 21 (such as a Si substrate) is provided. A plurality of fin structures 22 and a shallow trench isolation structure 23 are formed, a first transistor 11 is formed, and the first transistor 11 bonded the carrier wafer 16 is flipped, so that the substrate 21 is placed upward. The substrate 21 is removed, to expose the surface of the second fin structure 222 away from the first fin structure 221 (for the process, referring to the first to fifth steps in the first fabrication process of the stacked transistor described above) (see (a) in FIG. 8A).

At the second step, a fourth shallow trench isolation structure 234 is removed to expose a second fin structure 222, a first intermediate layer 223, and a shallow trench isolation layer 14 is formed (see (b) in FIG. 8A).

At the third step, amorphous carbon is deposited on the shallow trench isolation layer 14 to form a first semiconductor material layer 31 (see (c) in FIG. 8A).

At the fourth step, a layer of SiN material is atomically deposited on the first semiconductor material layer 31 and on the surface of the second fin structure 222, to form the second semiconductor material layer 32 (see (a) in FIG. 8B).

At the fifth step, the SiN material on the surface of the second fin structure 222 away from the first fin structure 221 and the SiN material on the first semiconductor material layer 31 are removed by anisotropic etching (see (b) in FIG. 8B).

At the sixth step, the first semiconductor material layer 31 is removed by anisotropic etching (see (c) in FIG. 8B).

At the seventh step, a SiN material is deposited on the surface of the second fin structure 222 away from the first fin structure 221 and on a partial region (the region not in contact with the first intermediate layer 223) on the shallow trench isolation layer 14, to form a third semiconductor material layer 33 (see (a) in FIG. 8C).

At the eighth step, the exposed first intermediate layer 223 is oxidized to form the isolation dielectric structure 13 (see (b) in FIG. 8C).

At the ninth step, the second semiconductor material layer 32 and the third semiconductor material layer 33 are removed to expose the second fin structure 222 (see (c) in FIG. 8C).

At the tenth step, the second transistor 12 is formed (for the process, referring to the fifteenth to seventeenth steps in the third fabrication process of the stacked transistors described above) (see FIG. 8D) Thus, the stacked transistor 10 in which the first transistor 11 and the second transistor 12 are fin-shaped field effect transistors and the first active structure 111 and the second active structure 121 are isolated by the isolation dielectric structure 13 has been fabricated by the fourth preparation method described above.

Note that, when the stacked transistor is a gate-all-around transistor, a planar transistor, or a vertical transistor, the fabrication method of the stacked transistor is the same as the fabrication method used when the stacked transistor is a fin-shaped field effect transistor in the above embodiment.

In an embodiment of the present disclosure, electrical isolation between the first active structure and the second active structure can be achieved by providing an isolation dielectric structure between the first active structure and the second active structure.

In the embodiment of the present disclosure, the fabrication method of the stacked transistor described above not only optimizes the process flow of the stacked transistor, but also takes the following issues into account: consistency, defect density, and alignment of the active regions of the upper and lower transistors (i.e., the first transistor and the second transistor). In addition, the above-mentioned fabrication method of the stacked transistor further solves for example the following long-term problems in the existing mainstream technical solutions of the stacked transistor: complex process, fixed type (monolithic solution), difficulty in alignment, and a high defect density of the upper semiconductor material (sequential solution), thereby promoting the industrialization of stacked transistor technology.

Secondly, the fabrication method of the stacked transistor described in the embodiment of the present disclosure is also an organic fusion of the current sequential and monolithic stacked transistor scheme, has a high degree of reuse of mature technologies, can avoid a large number of high process development to save costs, and has high feasibility. Also, in the embodiment of the present disclosure, the stacked transistor adopts a self-aligned “back-to-back” active region and metal gate design, and the front and back transistors (i.e., the first transistor and the second transistor) have independent signal and power supply networks, and are connected through local interconnection, so that the metal wiring resources are greatly released (which can be improved by more than 60%) without changing the extremely miniature 4T track unit design, and there is a huge space in the direction of collaborative optimization of process design. Finally, the isolation method of stacked transistors is compatible with existing mainstream device architectures, which can realize front and back stacking including the planar transistors, fin-shaped field effect transistors, nanosheet field effect transistors and even vertical field effect transistors (VTFETs) without performing specific process development for the architecture of specific devices. Therefore, the method has high flexibility, and has strong extensibility from the perspective of iteration of the semiconductor process node. The flipped stacked transistors are very advanced in concept, have important industrial value, and have strong practicability and broad expansion prospects.

The stacked transistors provided by embodiments of the present disclosure can be detected using a detection analysis instrument such as a scanning electron microscope (SEM), a transmission electron microscope (TEM), a scanning transmission electron microscope (STEM), and the like. Taking the TEM as an example, the stacked transistor provided by an embodiment of the present disclosure can detect an isolation dielectric structure located between a first active structure and a second active structure by a TEM slice.

The embodiments of the present disclosure provide a semiconductor device including the stacked transistor as described in the above-described embodiments. The stacked transistors can be defined with reference to the stacked transistors shown in FIGS. 2, 4, and 6 described above.

The embodiments of the present disclosure provide an electronic device including a circuit board and the semiconductor device as described in the above embodiment. The semiconductor device is disposed on the circuit board. The semiconductor device includes the stacked transistors described above. The stacked transistors can be defined with reference to the stacked transistors shown in FIGS. 2, 4, and 6 described above.

In the above-described embodiments, the description of various embodiment has different emphasis, and for parts not described in detail in a certain embodiment, reference may be made to the related description of other embodiments.

The foregoing is merely the exemplary specific embodiments of the present disclosure, but the scope of protection of the present disclosure is not limited thereto, and any changes or substitutions that can be easily conceived by those skilled in the art within the technical scope of the present disclosure should be covered within the scope of protection of the present disclosure. Therefore, the scope of protection of the present disclosure should be subject to the scope of protection of the claims.

1. A method of fabricating a stacked transistor, comprising:
forming a first active structure, a first intermediate layer and a second active structure which are disposed and stacked sequentially on a substrate;
forming a first transistor based on the first active structure;
flipping, and removing the substrate to expose the second active structure;
forming a second transistor based on the second active structure, wherein the first transistor and the second transistor are self-aligned in a direction perpendicular to a channel; and
forming an isolation dielectric structure based on the first intermediate layer, wherein a material of the isolation dielectric structure is different from a material of the first intermediate layer, and the isolation dielectric structure is used to isolate the first active structure from the second active structure.

2. The method of claim 1, further comprising: after the forming a first active structure, a first intermediate layer and a second active structure which are disposed and stacked sequentially on a substrate,
forming first dummy gate structures disposed at intervals on a surface of the first active structure and a first shallow trench isolation structure which coats the second active structure.

3. The method of claim 2, wherein the forming an isolation dielectric structure based on the first intermediate layer comprises:
removing the first intermediate layer to form a first gap; and
filling the first gap with an insulating material to form the isolation dielectric structure.

4. The method of claim 3, wherein the forming first dummy gate structures disposed at intervals on a surface of the first active structure and a first shallow trench isolation structure which coats the second active structure comprises:
forming a second shallow trench isolation structure which coats the first active structure, the first intermediate layer and the second active structure;
removing a portion of the second shallow trench isolation structure to expose the first active structure and the first intermediate layer and form the first shallow trench isolation structure; and
forming the first dummy gate structures based on the first active structure.

5. The method of claim 1, further comprising: before the forming a second transistor based on the second active structure,
depositing a first insulating material on a first surface of the first transistor facing the second active structure to form a first semiconductor material layer, wherein the first semiconductor material layer surrounds the first intermediate layer;
depositing a second insulating material on the second active structure and the first semiconductor material layer, to form a second semiconductor material layer, wherein the second semiconductor material layer coats the second active structure;
removing a part, covering the first semiconductor material layer, of the second semiconductor material layer to expose the first semiconductor material layer; and
removing the first semiconductor material layer to expose the first intermediate layer.

6. The method of claim 5, wherein the forming an isolation dielectric structure based on the first intermediate layer comprises:
performing an oxidation treatment on the first intermediate layer to form the isolation dielectric structure.

7. The method of claim 6, further comprising: before the forming a first transistor based on the first active structure,
depositing a dielectric material on the first active structure, the first intermediate layer and the second active structure, to form a shallow trench isolation structure, wherein the shallow trench isolation structure coats the first active structure, the first intermediate layer and the second active structure; and
removing a first portion of the shallow trench isolation structure to expose the first active structure.

8. The method of claim 7, further comprising: after the flipping and the removing the substrate to expose the second active structure,
removing a portion of the second active structure away from the first active structure, to form a first trench;
depositing a second insulating material in the first trench to form a first filling structure; and
removing a second portion of the shallow trench isolation structure, to expose the second active structure and the first intermediate layer.

9. The method of claim 8, wherein the removing a part, covering the first semiconductor material layer, of the second semiconductor material layer to expose the first semiconductor material layer comprises:
removing a part covering the first semiconductor material layer of the second semiconductor material layer, and a part covering the first filling structure of the second semiconductor material layer to expose the first semiconductor material layer and the first filling structure; and
performing an oxidation treatment on the first intermediate layer to form the isolation dielectric structure,
the method further comprises: removing the first filling structure and the second semiconductor material layer to expose the second active structure.

10. The method of claim 7, wherein the removing a part covering the first semiconductor material layer of the second semiconductor material layer to expose the first semiconductor material layer comprises:
removing a part covering the first semiconductor material layer of the second semiconductor material layer and a part covering a second surface of the second active structure of the second semiconductor material layer to expose the first semiconductor material layer and the second surface, wherein the second surface is a surface of the second active structure away from the first active structure.

11. The method of claim 10, further comprising: after the removing the first semiconductor material layer to expose the first intermediate layer,
depositing a second insulating material on the second surface and a first region of the first surface, to form a third semiconductor material layer, wherein the first region is not in contact with the second active structure, and
wherein the method further comprises: after the performing an oxidation treatment on the first intermediate layer to form the isolation dielectric structure, removing the second semiconductor material layer and the third semiconductor material layer to expose the second active structure.

12. A stacked transistor comprising:
a first transistor;
a second transistor, wherein the first transistor and the second transistor are self-aligned in a direction perpendicular to a channel; and
an isolation dielectric structure, wherein the isolation dielectric structure is positioned between a first active structure of the first transistor and a second active structure of the second transistor, and the isolation dielectric structure is used to isolate the first active structure from the second active structure.

13. A semiconductor device comprising the stacked transistor of claim 12.

14. An electronic device comprising a circuit board and the semiconductor device of claim 13, the semiconductor device being disposed on the circuit board.
